(19) United States
(12) Patent Application Publication
(10) Pub. No.: US 2026/0247662 A1
(43) Pub. Date: Aug. 20, 2026

(54) SEMICONDUCTOR DEVICE AND PRODUCTION METHOD THEREFOR

(71) Applicant: TOYODA GOSEI CO., LTD., Kiyosu-shi (JP)

(72) Inventor: Nariaki TANAKA, Kiyosu-shi (JP)

(21) Appl. No.: 19/543,318

(22) Filed: Feb. 18, 2026

(30) Foreign Application Priority Data
Feb. 19, 2025 (JP) 2025-024725

(51) Int. Cl. H10D 30/66; H10D 62/85; H10D 64/01; H10D 64/27

(52) U.S. Cl. CPC H10D 30/668; H10D 62/8503; H10D 64/025; H10D 64/513; H10D 64/518

(57) ABSTRACT

A semiconductor device includes: a semiconductor layer containing a p-type Group III nitride semiconductor; and an electrode located over the semiconductor layer, the electrode includes a first layer located over and in contact with the semiconductor layer and a second layer located over and in contact with the first layer, the first layer is made from a material containing Ni as a main component and containing 10% or less of Mg, and the second layer contains an alloy of Ni and Mg.

### CROSS-REFERENCE TO RELATED APPLICATION

This application is based on and claims priority under 35 USC 119 from Japanese Patent Application No. 2025-024725 filed on February 19, 2025.

### TECHNICAL FIELD

The present invention relates to a semiconductor device and a production method therefor.

### BACKGROUND ART

There is known a semiconductor device including a semiconductor layer made of a p-type Group III nitride semiconductor and an electrode provided on the semiconductor layer. For example, in a MOSFET using a Group III nitride semiconductor, there is known a structure in which a recess penetrating an n-type layer and reaching a p-type layer is provided and a body electrode is provided on the p-type layer.

Non Patent Literature 1 describes an electrode in which a Ni layer having a thickness of 25 nm, a Mg layer having a thickness of 8 nm, a Ni layer having a thickness of 25 nm, and a Si layer having a thickness of 240 nm are stacked on a p-GaN layer in order from a p-GaN layer side. The Mg layer in the electrode is used to increase a Mg concentration in the p-GaN layer. It is also disclosed that a heat treatment is performed at 200°C to 400°C for 30 minutes after the formation of the electrode.

Non Patent Literature 1: E. Kaminska et al., MRS Proc. 482, 1077 (1998)

### SUMMARY OF INVENTION

However, in the electrode in Non Patent Literature 1, when a heat treatment is performed, Mg comes into contact with the p-GaN layer, and contact resistance increases due to a work function. In addition, Si, which is an n-type dopant, diffuses from the Si layer in the electrode, resulting in an increase in contact resistance.

The present invention has been made in view of such a background, and an object of the present invention is to provide a semiconductor device including an electrode capable of reducing contact resistance to a p-type Group III nitride semiconductor.

An aspect of the present invention provides a semiconductor device including: a semiconductor layer made of a p-type Group III nitride semiconductor; and an electrode located on the semiconductor layer, in which the electrode includes a first layer located on and in contact with the semiconductor layer and a second layer located on and in contact with the first layer, the first layer is made of a material containing Ni as a main component and containing 10% or less of Mg, and the second layer contains an alloy of Ni and Mg.

Another aspect of the present invention provides a method for producing a semiconductor device including: forming, on a semiconductor layer made of a p-type Group III nitride semiconductor, an electrode in which a first Ni layer made of Ni, a Mg layer made of Mg, and a second Ni layer made of Ni are stacked in order from a semiconductor layer side at 100°C or lower, and then performing a heat treatment.

Still another aspect of the present invention provides a method for producing a semiconductor device including: forming, on a semiconductor layer made of a p-type Group III nitride semiconductor, an electrode in which a first Ni layer made of Ni, a Mg layer made of Mg, and a second Ni layer made of Ni are stacked in order from a semiconductor layer side, and then performing a heat treatment at a temperature of higher than 400°C and 600°C or lower.

Yet still another aspect of the present invention provides a method for producing a semiconductor device including: forming, on a semiconductor layer made of a p-type Group III nitride semiconductor, an electrode in which a first Ni layer made of Ni, a Mg layer made of Mg, and a second Ni layer made of Ni are stacked in order from a semiconductor layer side, and then performing a heat treatment for a time of 2 minutes or longer and 10 minutes or shorter.

In the above aspect, the electrode contains an alloy of Ni and Mg, and Mg is not in contact with the semiconductor layer, or even when Mg is in contact with the semiconductor layer, an amount of Mg can be reduced. Therefore, contact resistance of the electrode to the semiconductor layer can be reduced.

As described above, according to the above aspect, it is possible to provide a semiconductor device including an electrode capable of reducing contact resistance to a p-type Group III nitride semiconductor.

### BRIEF DESCRIPTION OF DRAWINGS

FIG. 1 is a cross-sectional view showing a configuration of a semiconductor device according to a first embodiment, which is a cross-sectional view perpendicular to a substrate main surface.

FIG. 2 is a cross-sectional view showing a configuration of a body electrode, which is a cross-sectional view perpendicular to a substrate main surface.

FIG. 3 is a flowchart showing steps of producing the semiconductor device according to the first embodiment.

FIG. 4 is a cross-sectional view showing a configuration of the semiconductor device according to the first embodiment in a production stage, which is a cross-sectional view perpendicular to the substrate main surface.

FIG. 5 is a cross-sectional view showing a configuration of the semiconductor device according to the first embodiment in a production stage, which is a cross-sectional view perpendicular to the substrate main surface.

FIG. 6 is a cross-sectional view showing a configuration of the semiconductor device according to the first embodiment in a production stage, which is a cross-sectional view perpendicular to the substrate main surface.

FIG. 7 is a flowchart showing steps of producing the body electrode.

FIG. 8 is a cross-sectional view showing a configuration of the body electrode in a production stage, which is a cross-sectional view perpendicular to the substrate main surface.

FIG. 9 is a cross-sectional view showing a configuration of the body electrode in a production stage, which is a cross-sectional view perpendicular to the substrate main surface.

FIG. 10 is a cross-sectional view showing a configuration of the body electrode in a production stage, which is a cross-sectional view perpendicular to the substrate main surface.

FIG. 11 is a cross-sectional TEM image of the body electrode before a heat treatment.

FIG. 12 shows element mapping of the body electrode before the heat treatment.

FIG. 13 is a cross-sectional TEM image of the body electrode after the heat treatment.

FIG. 14 shows element mapping of the body electrode after the heat treatment.

FIG. 15 is a graph showing an element concentration profile of the body electrode before the heat treatment.

FIG. 16 is an enlarged graph showing the vicinity of a Mg peak in FIG. 15.

FIG. 17 is a graph showing an element concentration profile of the body electrode after the heat treatment.

FIG. 18 is an enlarged graph showing the vicinity of a Mg peak in FIG. 17.

FIG. 19 is a graph showing a relationship between a heat treatment temperature and contact resistance.

FIG. 20 is a graph showing a relationship between the heat treatment temperature and the contact resistance.

FIG. 21 is a graph showing a relationship between a thickness ratio and the contact resistance.

FIG. 22 is a graph showing a relationship between the thickness ratio and the contact resistance.

FIG. 23 is a graph showing a relationship between a total thickness and the contact resistance.

FIG. 24 is a graph showing a relationship between a drain voltage Vd and a drain current Id.

FIG. 25 is a graph showing a relationship between the drain voltage Vd and the drain current Id.

FIG. 26 is a graph showing a relationship between a gate voltage Vg, the drain current Id, and a gate current Ig.

FIG. 27 is a graph showing a relationship between the gate voltage Vg, the drain current Id, and the gate current Ig.

### DESCRIPTION OF EMBODIMENTS

A semiconductor device includes: a semiconductor layer made of a p-type Group III nitride semiconductor; and an electrode located on the semiconductor layer, in which the electrode includes a first layer located on and in contact with the semiconductor layer and a second layer located on and in contact with the first layer, the first layer is made of a material containing Ni as a main component and containing 10% or less of Mg, and the second layer contains an alloy of Ni and Mg.

In the semiconductor device, the electrode may further include a third layer located on and in contact with the second layer and containing Ni as a main component.

In the semiconductor device, a thickness of the first layer may be 5 nm or more and 20 nm or less. The contact resistance of the electrode can be further reduced.

In the semiconductor device, a thickness of the second layer may be 5 nm or more and 20 nm or less. The contact resistance of the electrode can be further reduced.

In the semiconductor device, a thickness of the third layer may be 20 nm or more and 200 nm or less. The contact resistance of the electrode can be further reduced.

In the semiconductor device, a ratio of a thickness of the second layer to a total thickness of the electrode may be 0.02 or more and 0.35 or less. The contact resistance of the electrode can be further reduced.

A method for producing a semiconductor device includes: forming, on a semiconductor layer made of a p-type Group III nitride semiconductor, an electrode in which a first Ni layer made of Ni, a Mg layer made of Mg, and a second Ni layer made of Ni are stacked in order from a semiconductor layer side at 100°C or lower, and then performing a heat treatment.

A method for producing a semiconductor device includes: forming, on a semiconductor layer made of a p-type Group III nitride semiconductor, an electrode in which a first Ni layer made of Ni, a Mg layer made of Mg, and a second Ni layer made of Ni are stacked in order from a semiconductor layer side, and then performing a heat treatment at a temperature of higher than 400°C and 600°C or lower.

A method for producing a semiconductor device includes: forming, on a semiconductor layer made of a p-type Group III nitride semiconductor, an electrode in which a first Ni layer made of Ni, a Mg layer made of Mg, and a second Ni layer made of Ni are stacked in order from a semiconductor layer side, and then performing a heat treatment for a time of 2 minutes or longer and 10 minutes or shorter.

In the method for producing a semiconductor device, the heat treatment may be performed at a temperature of higher than 400°C and 600°C or lower. The contact resistance of the electrode can be further reduced.

In the method for producing a semiconductor device, the heat treatment may be performed for a time of 2 minutes or longer and 10 minutes or shorter. The contact resistance of the electrode can be further reduced.

In the method for producing a semiconductor device, a thickness of the first Ni layer may be 5 nm or more and 20 nm or less. The contact resistance of the electrode can be further reduced.

In the method for producing a semiconductor device, a thickness of the Mg layer may be 5 nm or more and 20 nm or less. The contact resistance of the electrode can be further reduced.

In the method for producing a semiconductor device, a thickness of the second Ni layer may be 20 nm or more and 200 nm or less. The contact resistance of the electrode can be further reduced.

In the method for producing a semiconductor device, a ratio of a thickness of the Mg layer to a total thickness of the electrode may be 0.02 or more and 0.35 or less. The contact resistance of the electrode can be further reduced.

In the method for producing a semiconductor device, the first Ni layer and the second Ni layer may be formed by EB deposition, and the Mg layer may be formed by resistance heating deposition. The Mg layer can be formed with high accuracy.

### First Embodiment

### 1. Configuration of Semiconductor Device

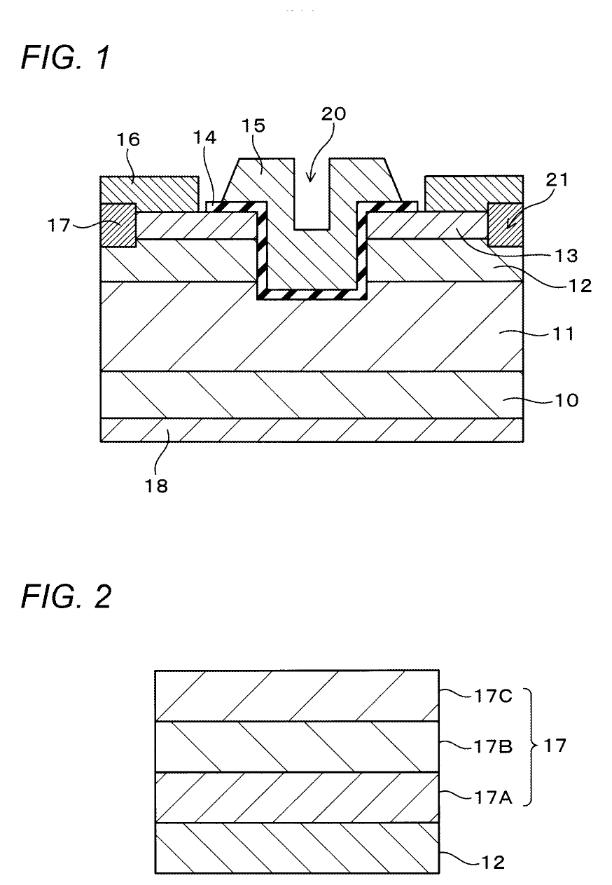

FIG. 1 is a cross-sectional view showing a configuration of a semiconductor device according to a first embodiment, which is a cross-sectional view perpendicular to a substrate main surface. As shown in FIG. 1, the semiconductor device according to the first embodiment includes a substrate 10, a first semiconductor layer 11, a second semiconductor layer 12, a third semiconductor layer 13, a gate insulating film 14, a gate electrode 15, a source electrode 16, a body electrode 17, and a drain electrode 18.

The substrate 10 is a substrate made of Si-doped n⁺-GaN having a c plane as a main surface. A Si concentration in the substrate 10 is 1 × 10¹⁸/cm³ or more.

The first semiconductor layer 11 is provided on the substrate 10 and is a semiconductor layer made of Si-doped n⁻-GaN. The first semiconductor layer 11 functions as a drift layer. A thickness of the first semiconductor layer 11 is 8 μm to 15 μm. In addition, a Si concentration in the first semiconductor layer 11 is 1 × 10¹⁵/cm³ to 2 × 10¹⁶/cm³.

The second semiconductor layer 12 is provided on the first semiconductor layer 11 and is a semiconductor layer made of Mg-doped p-GaN. The second semiconductor layer 12 functions as a channel layer. A thickness of the second semiconductor layer 12 is 0.1 μm to 1 μm. In addition, a Mg concentration in the second semiconductor layer 12 is 1 × 10¹⁷/cm³ to 8 × 10¹⁹/cm³.

The third semiconductor layer 13 is provided on the second semiconductor layer 12 and is a semiconductor layer made of Si-doped n⁺-GaN. The third semiconductor layer 13 functions as a source contact layer. A thickness of the third semiconductor layer 13 is 0.1 μm to 0.5 μm. In addition, a Si concentration in the third semiconductor layer 13 is 1 × 10¹⁸/cm³ to 1 × 10¹⁹/cm³.

A trench 20 is formed in a partial region of a surface of the third semiconductor layer 13. The trench 20 is a recessed portion having a depth reaching the first semiconductor layer 11 penetrating the third semiconductor layer 13 and the second semiconductor layer 12. The first semiconductor layer 11 is exposed at a bottom surface of the trench 20. The first semiconductor layer 11, the second semiconductor layer 12, and the third semiconductor layer 13 are exposed on a side surface of the trench 20 in order from a bottom surface side. The second semiconductor layer 12 exposed on the side surface of the trench 20 functions as a channel.

A recess 21 is provided in a partial region in the third semiconductor layer 13 that is different from a formation region of the trench 20. The recess 21 is a recessed portion having a depth reaching the second semiconductor layer 12 penetrating the third semiconductor layer 13.

The gate insulating film 14 is provided in a film shape continuously over the bottom surface, the side surface, and an upper surface of the trench 20 (a region near the trench 20 in the surface of the third semiconductor layer 13). The gate insulating film 14 is made of SiO₂, for example.

The gate electrode 15 is an electrode provided over the bottom surface, the side surface, and the upper surface of the trench 20 via the gate insulating film 14. The gate electrode 15 is made of TiN, for example.

The body electrode 17 is an electrode provided on a bottom surface of the recess 21. Since the second semiconductor layer 12 is exposed at the bottom surface of the recess 21, the body electrode 17 is located on and in contact with the second semiconductor layer 12. The body electrode 17 may be in contact with the third semiconductor layer 13 on a side surface of the recess 21. The body electrode 17 may be formed from the side surface of the recess 21 to an upper surface of the recess 21 (a region near the recess 21 in the surface of the third semiconductor layer 13). Details of the structure of the body electrode 17 will be described later.

The source electrode 16 is an electrode provided on the third semiconductor layer 13 and the body electrode 17. The source electrode 16 is formed of, for example, a multilayer film in which Pd, Al, and Ti are stacked in order from a third semiconductor layer 13 or body electrode 17 side.

The drain electrode 18 is an electrode provided on a back surface of the substrate 10. The drain electrode 18 is made of Pd/Al/Ti, for example.

### 2. Configuration of Body Electrode 17

Next, a configuration of the body electrode 17 will be described with reference to FIG. 2. As shown in FIG. 2, the body electrode 17 includes a first layer 17A located on and in contact with the second semiconductor layer 12, a second layer 17B located on and in contact with the first layer 17A, and a third layer 17C located on and in contact with the second layer 17B.

The first layer 17A is made of a material containing Ni as a main component and containing 10% or less of Mg. By using such a material, an amount of contact between the second semiconductor layer 12 and Mg atoms in the first layer 17A is reduced, thereby preventing deterioration of contact resistance of the body electrode 17 to the second semiconductor layer 12. The material of the first layer 17A is more preferably a material containing Ni as a main component and containing 8% or less of Mg, and still more preferably a material containing Ni as a main component and containing 5% or less of Mg.

In addition, the first layer 17A may contain N. For example, N is 20% or less, and preferably 5% to 15%. In addition, the first layer 17A may contain Ga. For example, Ga is 20% or less, and preferably 5% to 15%.

A thickness of the first layer 17A is preferably 5 nm to 20 nm. Within such a range, the contact resistance of the body electrode 17 to the second semiconductor layer 12 can be further reduced. When the thickness of the first layer 17A is less than 5 nm, the contact between the second semiconductor layer 12 and Mg increases, and there is a possibility that the contact resistance deteriorates. In addition, when the thickness of the first layer 17A is increased, a distance between the second semiconductor layer 12 and the second layer 17B increases, and there is a possibility that the contact resistance deteriorates. The thickness of the first layer 17A is more preferably 5 nm to 15 nm, and still more preferably 5 nm to 10 nm.

The second layer 17B is made of a material containing an alloy of Ni and Mg. By using a layer containing such an alloy of Ni and Mg, the contact resistance of the body electrode 17 to the second semiconductor layer 12 can be reduced. A proportion of the alloy of Ni and Mg in the second layer 17B is preferably 50 mol% or more. Within this range, the contact resistance of the body electrode 17 to the second semiconductor layer 12 can be further reduced. The proportion of the alloy of Ni and Mg in the second layer 17B is more preferably 60 mol%, and still more preferably 80 mol%.

In the second layer 17B, a Ni concentration is, for example, 30% to 60%, and a Mg concentration is, for example, 40% to 70%. In addition, the second layer 17B may have a region having a high Ni concentration and a region having a low Ni concentration in a direction parallel to a main surface of the substrate 10. For example, it may have a region where Ni is 30% or less and a region where Ni is 40% or more.

In addition, the second layer 17B may contain N. In addition, a N concentration in the second layer 17B may be higher than that in the first layer 17A. For example, the N concentration in the second layer 17B is 20% or less, and preferably 5% to 15%. In addition, the second layer 17B may have a region having a high N concentration and a region having a low N concentration in the direction parallel to the main surface of the substrate 10. For example, it may have a region where N is 5% or less and a region where N is 10% or more.

In addition, the second layer 17B may contain Ga. For example, a Ga concentration in the second layer 17B is 10% or less, and preferably 5% or less.

A thickness of the second layer 17B is preferably 5 nm to 20 nm. Within such a range, the contact resistance of the body electrode 17 to the second semiconductor layer 12 can be further reduced. When the thickness of the second layer 17B is less than 5 nm, an amount of the alloy of Ni and Mg is reduced, and as a result, there is a possibility that the contact resistance deteriorates. In addition, when the thickness of the second layer 17B is increased, there is a high possibility that Mg diffuses and comes into contact with the second semiconductor layer 12, and as a result, there is a possibility that the contact resistance deteriorates. The thickness of the second layer 17B is more preferably 5 nm to 15 nm, and still more preferably 5 nm to 10 nm.

The third layer 17C is made of Ni or a material containing Ni as a main component. The third layer 17C is provided as a cap layer that protects the second layer 17B from oxidation, nitriding, and the like.

The third layer 17C may contain Mg or may form an alloy of Ni and Mg. For example, a Mg concentration is 10% or less, and preferably 5% or less. In addition, the third layer 17C may contain N. For example, a N concentration is 10% or less. In addition, the third layer 17C may contain Ga. For example, a Ga concentration is 5% or less.

A thickness of the third layer 17C is preferably 20 nm to 200 nm. Within such a range, the contact resistance of the body electrode 17 to the second semiconductor layer 12 can be further reduced. The thickness of the third layer 17C is more preferably 5 nm to 15 nm, and still more preferably 5 nm to 10 nm.

A total thickness of the first layer 17A and the second layer 17B is preferably 10 nm to 30 nm. In addition, a total thickness of the first layer 17A and the third layer 17C is preferably 40 nm to 60 nm. In addition, a total thickness of the second layer 17B and the third layer 17C is preferably 40 nm to 60 nm. Within such a range, the contact resistance of the body electrode 17 to the second semiconductor layer 12 can be further reduced.

A ratio of the thickness of each layer of the body electrode 17 is preferably as follows. The contact resistance of the body electrode 17 to the second semiconductor layer 12 can be further reduced.

A ratio of the thickness of the second layer 17B to a total thickness of the body electrode 17 (that is, a total thickness of the first layer 17A, the second layer 17B, and the third layer 17C) is preferably 0.02 to 0.35.

A ratio of the total thickness of the first layer 17A and the second layer 17B to the total thickness of the body electrode 17 is preferably 0.1 to 0.6.

A ratio of the thickness of the second layer 17B to the total thickness of the first layer 17A and the second layer 17B is preferably 0.1 to 0.4.

A ratio of the thickness of the first layer 17A to the thickness of the third layer 17C is preferably 0.1 to 0.9. In addition, a ratio of the thickness of the second layer 17B to the thickness of the third layer 17C is preferably 0.1 to 0.4. In addition, a ratio of the thickness of the first layer 17A to the thickness of the second layer 17B is preferably 0.2 to 0.9.

According to the body electrode 17 described above, since Mg in the body electrode 17 is not in contact with the second semiconductor layer 12 made of a p-type Group III nitride semiconductor and an alloy of Ni and Mg is generated, the contact resistance to the second semiconductor layer 12 can be reduced.

### 3. Method for Producing Semiconductor Device

Next, a method for producing a semiconductor device according to the first embodiment will be described with reference to the drawings.

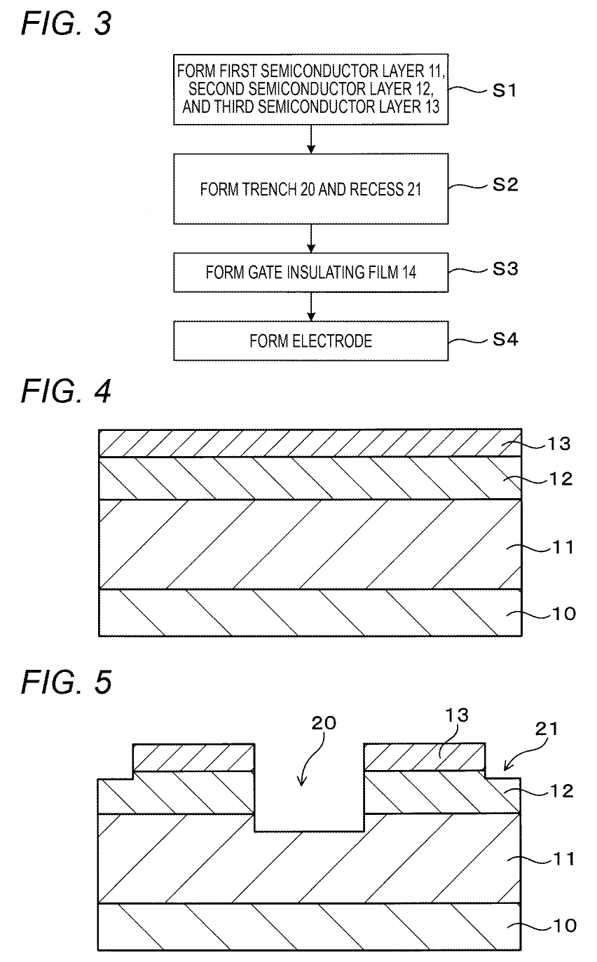

First, the first semiconductor layer 11, the second semiconductor layer 12, and the third semiconductor layer 13 are formed on the substrate 10 in order from a substrate 10 side (see step S1 in FIGS. 3 and FIG. 4). A method of forming the first semiconductor layer 11, the second semiconductor layer 12, and the third semiconductor layer 13 is, for example, MOCVD.

Next, a predetermined region on the surface of the third semiconductor layer 13 is dry-etched to reach the first semiconductor layer 11 to form the trench 20. Then, a predetermined region on the surface of the third semiconductor layer 13 is dry-etched to reach the second semiconductor layer 12 to form the recess 21 (see step S2 in FIGS. 2 and FIG. 5). A wet etching process may be added after the trench 20 and the recess 21 are formed by dry etching.

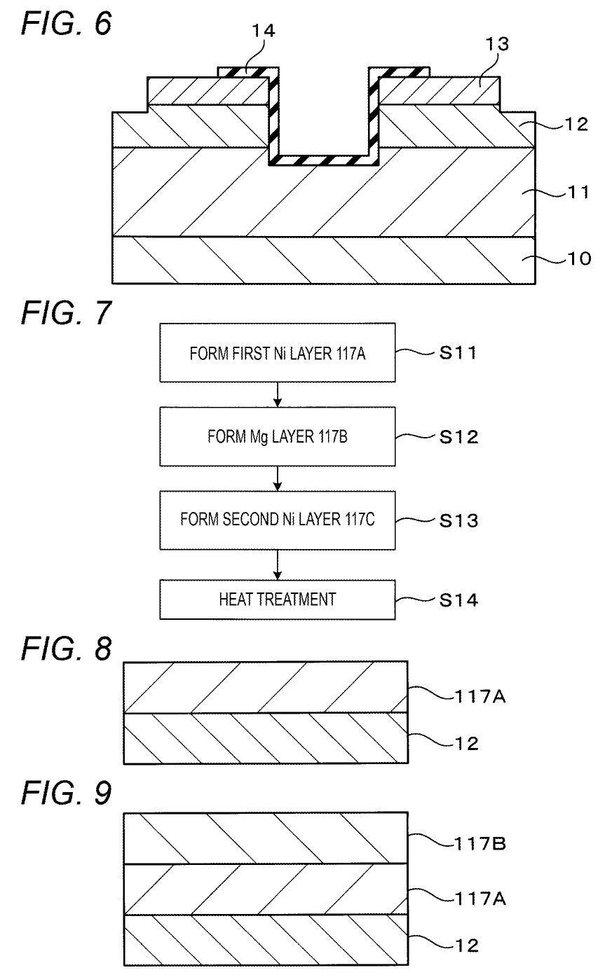

Next, the gate insulating film 14 is formed in a film shape continuously on the bottom surface, the side surface, and the upper surface of the trench 20 (see step S3 in FIGS. 3 and FIG. 6).

Next, the gate electrode 15 is formed on the bottom surface, the side surface, and the upper surface of the trench 20 via the gate insulating film 14. Next, the body electrode 17 is formed on the bottom surface of the recess 21. A detailed method of forming the body electrode 17 will be described later. Next, the source electrode 16 is formed on the third semiconductor layer 13 and the body electrode 17. Next, the drain electrode 18 is formed on the back surface of the substrate 10. Here, a heat treatment on the body electrode 17 and the source electrode 16 may be performed collectively or individually. A heat treatment on the drain electrode 18 is performed separately from the heat treatment on the body electrode 17 and the source electrode 16. These electrodes are formed by, for example, deposition or sputtering. With the above, the semiconductor device according to the first embodiment shown in FIG. 1 is produced.

### 4. Method of Forming Body Electrode 17

Next, the method of forming the body electrode 17 will be described with reference to the drawings.

First, a first Ni layer 117A is formed on and in contact with the second semiconductor layer 12 by deposition (see step S11 in FIGS. 7 and FIG. 8). The deposition method is EB deposition or the like. A temperature during formation (a temperature of the substrate 10) is preferably 100°C or lower.

Next, a Mg layer 117B is formed on and in contact with the first Ni layer 117A by deposition (see step S12 in FIGS. 7 and FIG. 9). The deposition method is preferably resistance heating deposition. Since Mg is easily evaporated, it is difficult to form the Mg layer 117B uniformly, but the Mg layer 117B can be formed with high accuracy by using resistance heating deposition. The Mg layer 117B may be formed by sputtering instead of deposition.

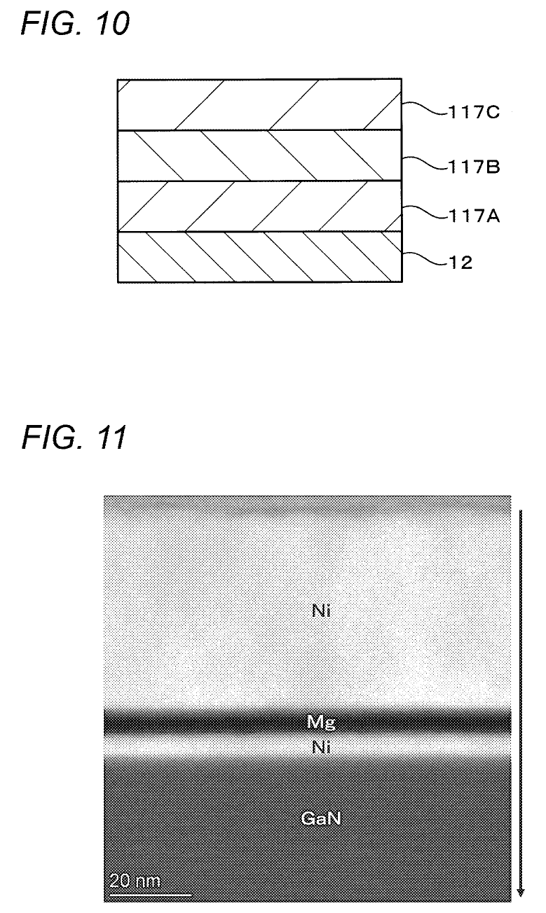

Next, a second Ni layer 117C is formed on and in contact with the Mg layer 117B by deposition (see step S13 in FIG. 7 and FIG. 10). The deposition method is EB deposition or the like.

A temperature (substrate temperature) in forming the first Ni layer 117A, the Mg layer 117B, and the second Ni layer 117C is preferably 100°C or lower. By formation at 100°C or lower, the first Ni layer 117A, the Mg layer 117B, and the second Ni layer 117C can be formed uniformly with high accuracy, and as a result, the contact resistance can be further reduced. The formation temperature is more preferably 60°C or lower. A lower limit of the formation temperature is, for example, 0°C. It may be formed at room temperature.

Next, a heat treatment is performed on the body electrode 17 (step S14 in FIG. 7). This heat treatment may also serve as a heat treatment for another electrode, or may be performed separately. A heat treatment atmosphere is an inert gas atmosphere such as nitrogen or rare gas. In addition, a heat treatment pressure is normal pressure.

A heat treatment temperature is preferably higher than 400°C and 600°C or lower. By setting the heat treatment temperature within such a range, the contact resistance of the body electrode 17 to the second semiconductor layer 12 can be further reduced. The heat treatment temperature is more preferably 450°C to 600°C, and still more preferably 500°C to 575°C.

A heat treatment time is preferably 2 minutes to 10 minutes. By setting the heat treatment time within such a range, the contact resistance of the body electrode 17 to the second semiconductor layer 12 can be further reduced. The heat treatment time is preferably 5 minutes to 10 minutes.

With this heat treatment, Mg in the Mg layer 117B slightly diffuses into the first Ni layer 117A. However, Mg is not in contact with the second semiconductor layer 12, or even when Mg is in contact with the second semiconductor layer 12, an amount of Mg is small. Therefore, the deterioration of the contact resistance of the body electrode 17 due to diffusion of Mg into the first Ni layer 117A is prevented.

In addition, Ni in the first Ni layer 117A and Ni in the second Ni layer 117C diffuse into the Mg layer 117B. Then, the diffused Ni forms an alloy with Mg in the Mg layer 117B. Since the alloy of Ni and Mg is formed in this manner, the contact resistance of the body electrode 17 can be reduced.

In addition, N in the second semiconductor layer 12 may diffuse into the Mg layer 117B, and N may be contained in a part or all of the Mg layer 117B. In addition, Mg in the Mg layer 117B may diffuse into the second Ni layer 117C, or N in the second semiconductor layer 12 may diffuse into the second Ni layer 117C.

In this manner, since the diffusion of atoms occurs due to the heat treatment, the body electrode 17 changes from a stacked structure of the first Ni layer 117A, the Mg layer 117B, and the second Ni layer 117C to a stacked structure of the first layer 17A, the second layer 17B, and the third layer 17C in order from a second semiconductor layer 12 side.

Note that, the thickness of each layer is hardly changed by the heat treatment. That is, the thicknesses of the first layer 17A and the first Ni layer 117A, the thicknesses of the second layer 17B and the Mg layer 117B, and the thicknesses of the third layer 17C and the second Ni layer 117C are substantially equal to each other. Therefore, preferred ranges of the thickness and the ratio of the first Ni layer 117A, the Mg layer 117B, and the second Ni layer 117C are the same as those of the first layer 17A, the second layer 17B, and the third layer 17C.

According to the method of forming the body electrode 17 described above, the alloy of Ni and Mg can be formed, and Mg is not in contact with the second semiconductor layer 12, or even when Mg is in contact with the second semiconductor layer 12, the amount of Mg can be reduced. Therefore, the body electrode 17 having low contact resistance to the second semiconductor layer 12 can be formed.

### 5. Various Experiment Results

Next, various experiment results related to the first embodiment will be described.

### Experiment 1

A p-GaN layer was formed on an n-GaN substrate, then the body electrode 17 was formed on the p-GaN layer, and the body electrode 17 was analyzed by TEM-EDS. The analysis was performed both before and after a heat treatment. The heat treatment was performed at 550°C for 5 minutes in a nitrogen atmosphere. The thickness of the first Ni layer 117A was 5 nm, the thickness of the Mg layer 117B was 5 nm, and the thickness of the second Ni layer 117C was 50 nm. In addition, the p-GaN layer had a thickness of 1 μm and a Mg concentration of 1 × 10¹⁹/cm³.

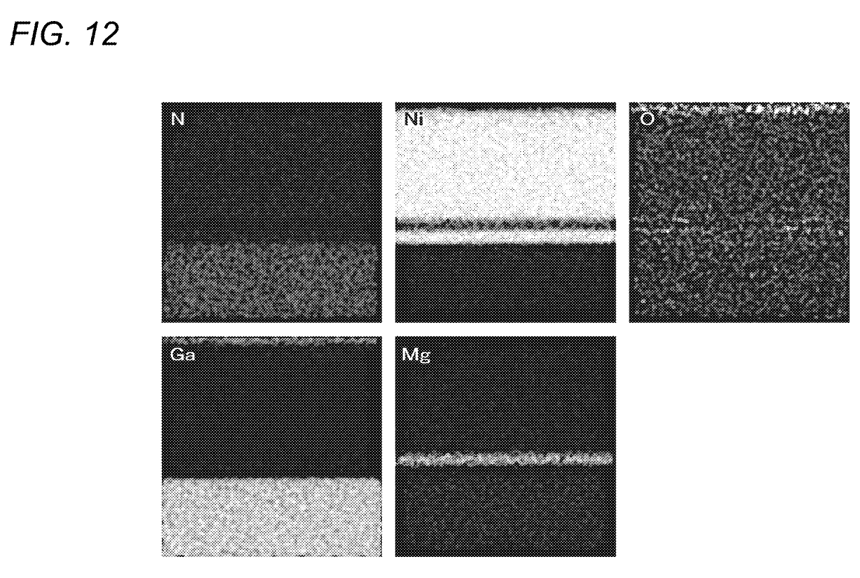

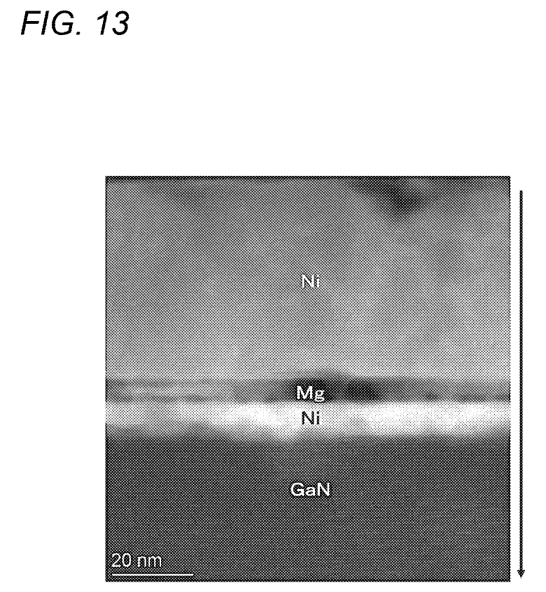

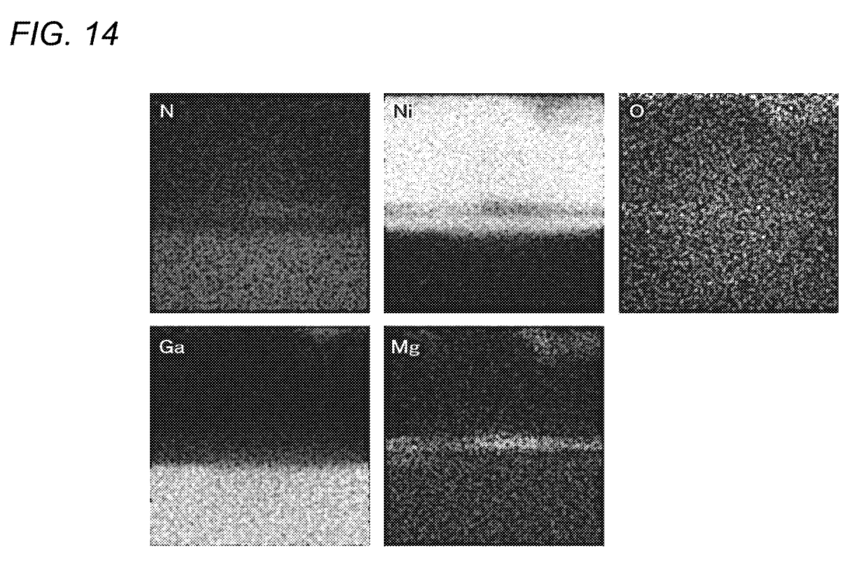

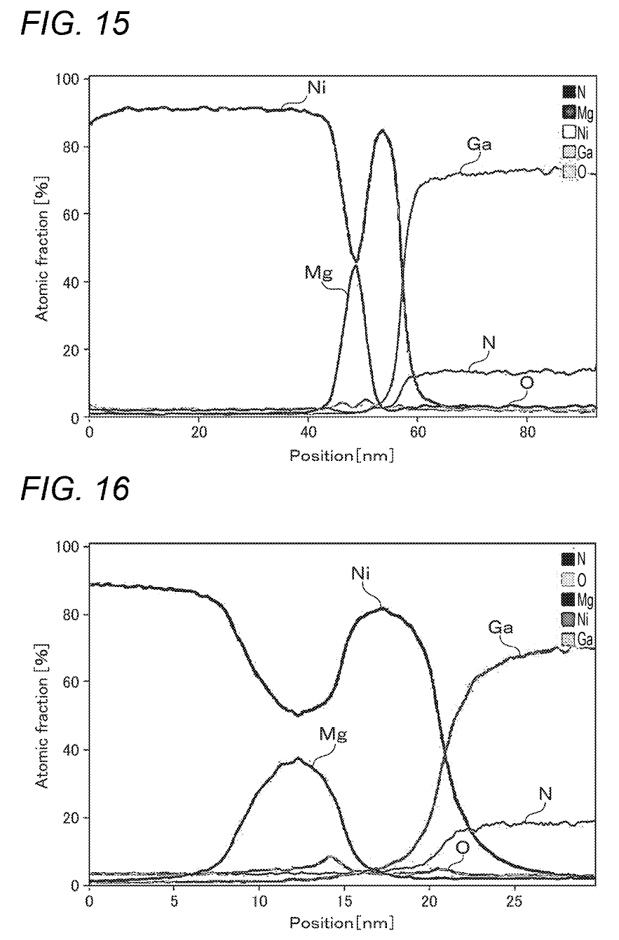

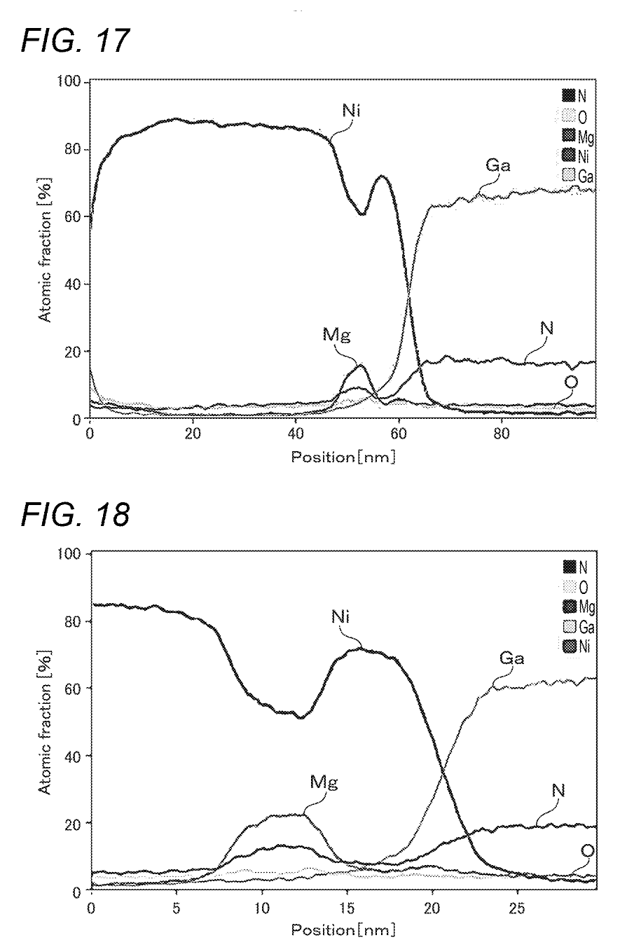

FIG. 11 is a cross-sectional TEM image of the body electrode 17 before the heat treatment, and FIG. 12 is EDS mapping of the body electrode 17 before the heat treatment. FIG. 13 is a cross-sectional TEM image of the body electrode 17 after the heat treatment, and FIG. 14 is EDS mapping of the body electrode 17 after the heat treatment. FIG. 15 is a graph showing an element concentration profile of the body electrode 17 before the heat treatment, and FIG. 16 is an enlarged graph showing the vicinity of a Mg peak in FIG. 15. FIG. 17 is a graph showing an element concentration profile of the body electrode 17 after the heat treatment, and FIG. 18 is an enlarged graph showing the vicinity of a Mg peak in FIG. 17. A horizontal axis in FIGS. 15 to 18 represents a depth in a direction from a surface of the body electrode 17 toward the p-GaN layer.

As shown in FIGS. 11, 12, 15, and 16, it can be seen that the body electrode 17 before the heat treatment is a stack of three layers including the first Ni layer 117A made of Ni, the Mg layer 117B made of Mg, and the second Ni layer 117C made of Ni.

In addition, as shown in FIGS. 13, 14, 17, and 18, it can be seen that in the body electrode 17 after the heat treatment, the stacking of the three layers is maintained, but diffusion of atoms occurs.

As shown in FIGS. 14, 17, and 18, it can be seen that Mg in the Mg layer 117B diffuses and the Mg concentration decreases, and Mg diffuses into the first Ni layer 117A and the second Ni layer 117C, but the diffusion of Mg into the first Ni layer 117A is small, and Mg is not in contact with the p-GaN layer or even when Mg is in contact with the p-GaN layer, the amount of Mg is small.

As shown in FIGS. 14, 17 and 18, Ni in the first Ni layer 117A and Ni in the second Ni layer 117C diffuse into the Mg layer 117B. Therefore, it is considered that the alloy of Ni and Mg is formed. In addition, N in the p-GaN layer diffuses into a partial region of the Mg layer 117B, and the Ni concentration decreases in the region. In FIG. 13, shading occurs in the Mg layer 117B, but this is considered to reflect the N concentration in the Mg layer 117B with reference to FIG. 14.

In addition, from FIGS. 17 and 18, the Ni concentration is 60%, the Mg concentration is 10%, the Ga concentration is 20%, and the N concentration is 10% at an interface between the p-GaN layer and the first Ni layer 117A. In addition, the Ni concentration is 60%, the Mg concentration is 20%, and the N concentration is 10% at an interface between the first Ni layer 117A and the Mg layer 117B.

Note that, in the element concentration profile in FIGS. 15 to 18, there is a Mg peak in the region of the Mg layer 117B, but the Mg concentration is lower than the actual Mg concentration. This is because the Mg concentration in the Mg layer 117B appears low due to signal fluctuations of the first Ni layer 117A and the second Ni layer 117C. In FIGS. 15 and 16, the Mg concentration at the Mg peak is about 40%, but is considered to be actually a value close to 100%. In FIGS. 17 and 18, the Mg concentration at the Mg peak is about 20%, but is considered to be actually about 40% to 60%.

### Experiment 2

A p-GaN layer was formed on an n-GaN substrate, then a TLM electrode pattern was formed on the p-GaN layer, a heat treatment was performed, and the contact resistance of various electrodes to the p-GaN layer was measured. The thickness and the Mg concentration in the p-GaN layer were the same as those in Experiment 1.

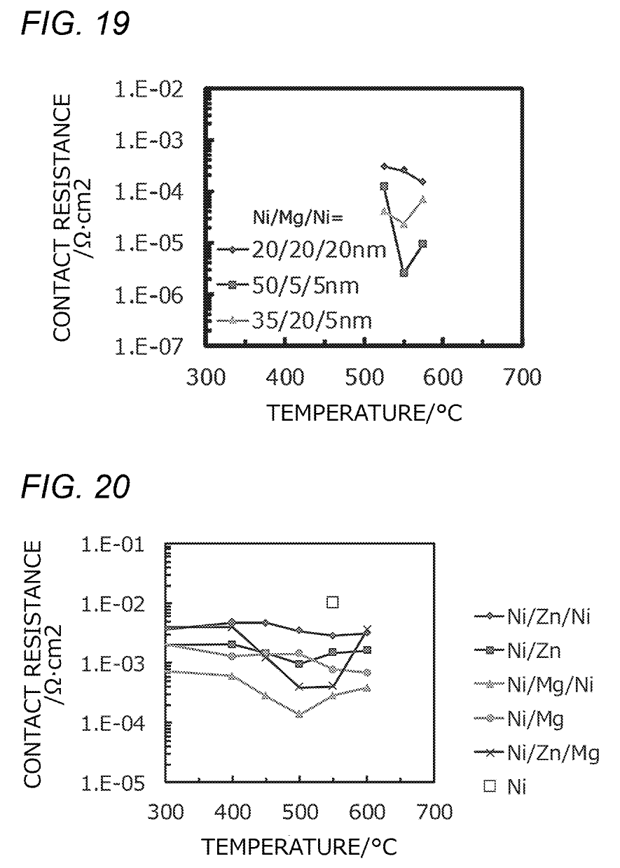

FIG. 19 is a graph showing a relationship between the heat treatment temperature and the contact resistance when an electrode material is Ni/Mg/Ni. Here, "/" means stacking, and A/B means stacking in order of B and A from a p-GaN layer side. Hereinafter, the same applies to the description of the electrode material. The thickness of each layer of Ni/Mg/Ni was set to three types: 20 nm/20 nm/20 nm, 50 nm/5 nm/5 nm, and 35 nm/20 nm/5 nm. Here, the order of thickness corresponds to the order of Ni/Mg/Ni. The same applies to the following description of the thickness.

As shown in FIG. 19, it is seen that when the electrode material is Ni/Mg/Ni, the contact resistance can be 1 × 10⁻⁴ Ω·cm² or less by setting the heat treatment temperature to 500°C to 600°C. In addition, it is inferred, from FIG. 19, that the thickness of the first Ni layer 117A is preferably 5 nm to 20 nm and the thickness of the Mg layer 117B is preferably 5 nm to 20 nm.

FIG. 20 is a graph showing a relationship between the heat treatment temperature and the contact resistance for various electrode materials. The electrode materials were six types: Ni/Zn/Ni, Ni/Zn, Ni/Mg/Ni, Ni/Mg, Ni/Zn/Mg, and Ni. The thickness of each layer of Ni/Zn/Ni was 20 nm/20 nm/20 nm, the thickness of each layer of Ni/Zn was 40 nm/20 nm, the thickness of each layer of Ni/Mg/Ni was 20 nm/20 nm/20 nm, the thickness of each layer of Ni/Mg was 40 nm/20 nm, the thickness of each layer of Ni/Zn/Mg was 20 nm/20 nm/20 nm, and the thickness of Ni was 50 nm.

As shown in FIG. 20, it is seen that the contact resistance can be reduced by using Ni/Mg/Ni as compared with other materials.

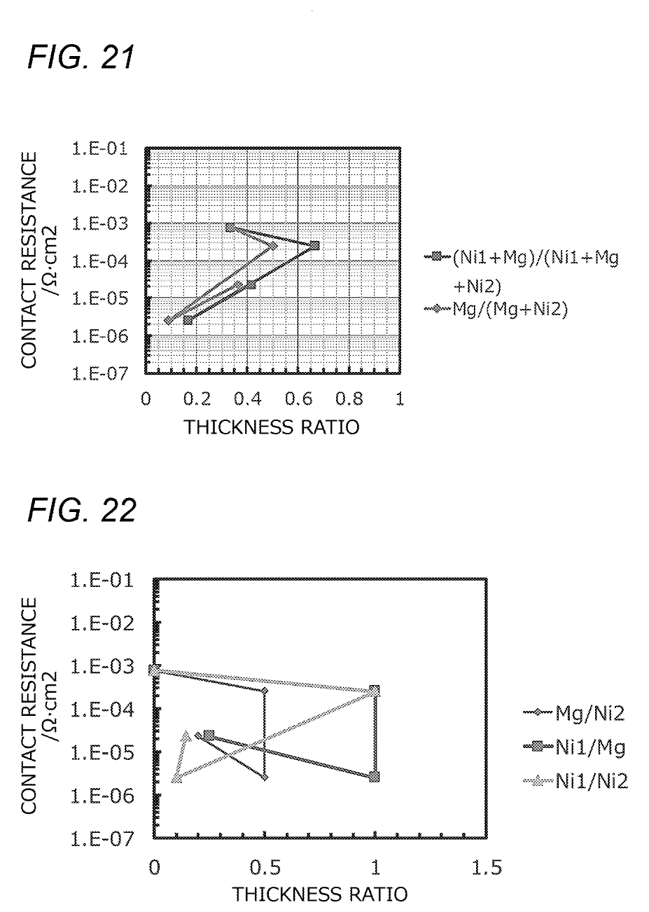

FIG. 21 is a graph showing a relationship between the thickness ratio of each layer and the contact resistance when the electrode material is Ni/Mg/Ni. The thickness ratio is two types: a ratio of a total thickness of the first layer (Ni) and the second layer (Mg) to a total thickness of Ni/Mg/Ni, and a ratio of a thickness of the second layer (Mg) to a total thickness of the second layer (Mg) and the third layer (Ni).

As shown in FIG. 21, it is seen that, in order to further reduce the contact resistance (specifically, in order to set the contact resistance to 1 × 10⁻⁴ Ω·cm² or less), the ratio of the total thickness of the first layer (Ni) and the second layer (Mg) to the total thickness of Ni/Mg/Ni is preferably 0.1 to 0.6, and the ratio of the thickness of the second layer (Mg) to the total thickness of the second layer (Mg) and the third layer (Ni) is preferably 0.05 to 0.4.

FIG. 22 is a graph showing a relationship between the thickness ratio of each layer and the contact resistance when the electrode material is Ni/Mg/Ni. The thickness ratio is three types: a ratio of the thickness of the second layer (Mg) to the thickness of the third layer (Ni), a ratio of the thickness of the first layer (Ni) to the thickness of the second layer (Mg), and a ratio of the thickness of the first layer (Ni) to the thickness of the third layer (Ni).

As shown in FIG. 22, it is seen that, in order to further reduce the contact resistance, the ratio of the thickness of the second layer (Mg) to the thickness of the third layer (Ni) is preferably 0.1 to 0.5, the ratio of the thickness of the first layer (Ni) to the thickness of the second layer (Mg) is preferably 0.2 to 1, and the ratio of the thickness of the first layer (Ni) to the thickness of the third layer (Ni) is preferably 0.1 to 1.

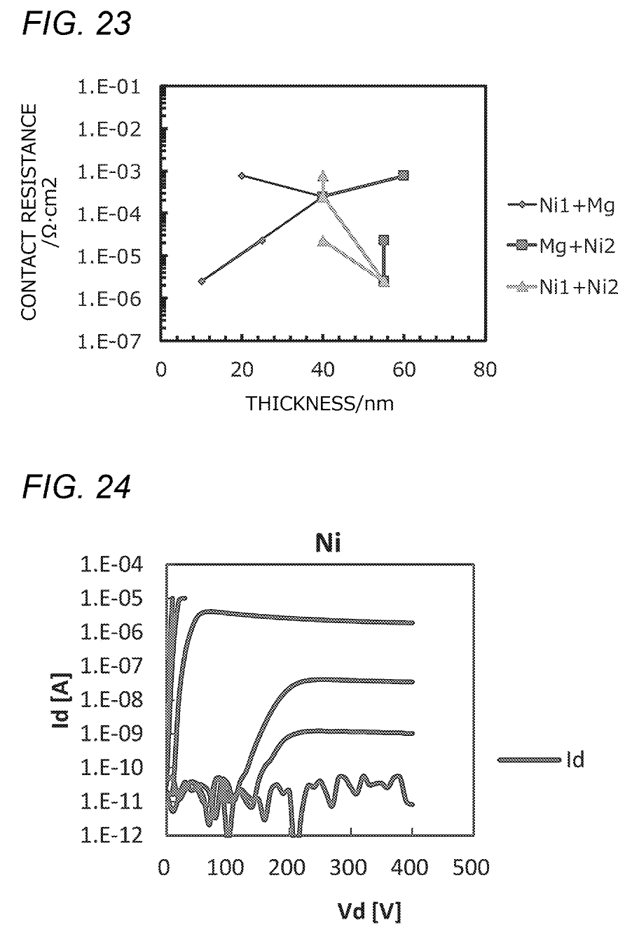

FIG. 23 is a graph showing a relationship between the total thickness of each layer and the contact resistance when the electrode material is Ni/Mg/Ni. The total thickness is three types: a total thickness of the first layer (Ni) and the second layer (Mg), a total thickness of the second layer (Mg) and the third layer (Ni), and a total thickness of the first layer (Ni) and the third layer (Ni).

As shown in FIG. 23, it is seen that, in order to further reduce the contact resistance, the total thickness of the first layer (Ni) and the second layer (Mg) is preferably 10 nm to 40 nm, the total thickness of the second layer (Mg) and the third layer (Ni) is preferably 45 nm to 65 nm, and the total thickness of the first layer (Ni) and the third layer (Ni) is preferably 45 nm to 60 nm.

### Experiment 3

A semiconductor device according to the first embodiment was prepared, and I-V properties of the semiconductor device were determined. For comparison, the I-V properties were also determined for a semiconductor device in which the body electrode 17 was made of Ni and the other configurations were the same as those in the first embodiment.

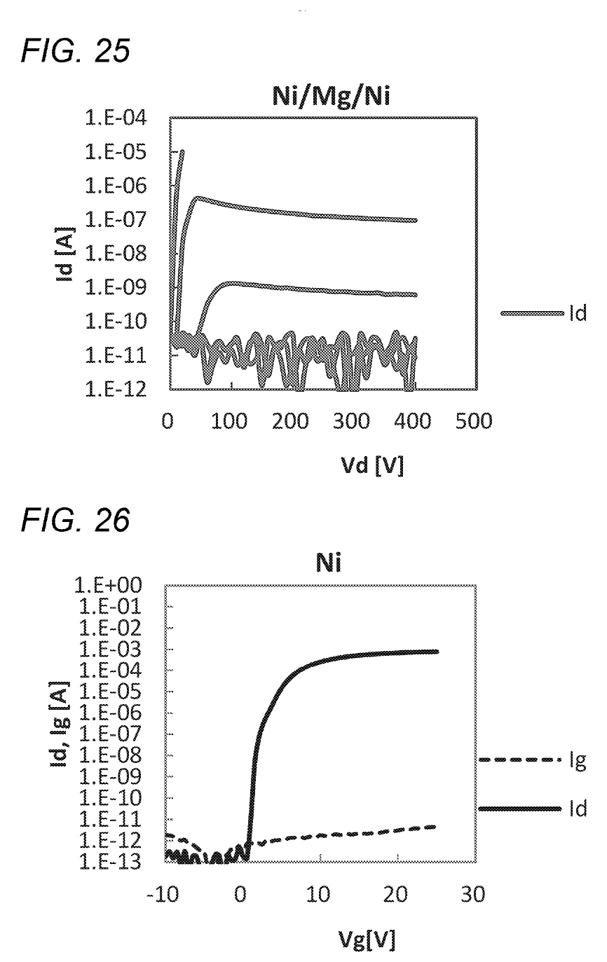

FIG. 24 is a graph showing a relationship between a drain voltage Vd and a drain current Id when the body electrode 17 is made of Ni, and FIG. 25 is a graph showing a relationship between the drain voltage Vd and the drain current Id when the body electrode 17 is made of the material in the first embodiment.

As shown in FIGS. 24 and 25, by changing the material of the body electrode 17 from Ni to the material in the first embodiment, a gate threshold voltage is increased, and a gate voltage is increased by 2 V when the drain current Id is on the order of 1 nA.

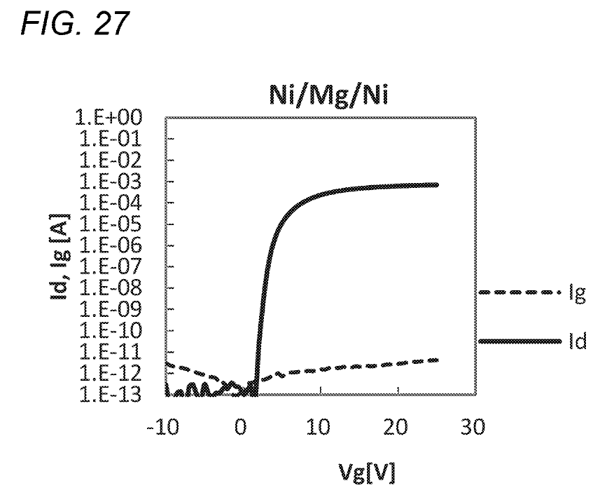

FIG. 26 is a graph showing a relationship between a gate voltage Vg, the drain current Id, and the gate current Ig when the body electrode 17 is made of Ni. FIG. 27 is a graph showing a relationship between Vg, Id, and Ig when the body electrode 17 is made of the material in the first embodiment.

As shown in FIGS. 26 and 27, by changing the material of the body electrode 17 from Ni to the material in the first embodiment, the gate voltage Vg is increased by 0.5 V when the drain current Id is 1 nA. Even when the material of the body electrode 17 is changed from Ni to the material in the first embodiment, no deterioration such as an increase in gate current Ig is observed.

### Other Modifications

While the semiconductor device according to the first embodiment is the MOSFET including the body electrode 17 in contact with the second semiconductor layer 12 made of a p-type Group III nitride semiconductor, the present invention is not limited to the MOSFET but can be applied to any semiconductor device including an electrode on and in contact with a semiconductor layer made of a p-type Group III nitride semiconductor. For example, the present invention is also applicable to an anode electrode of an LED, a diode, or the like.

### REFERENCE SIGNS LIST

10: substrate

11: first semiconductor layer

12: second semiconductor layer

13: third semiconductor layer

14: gate insulating film

15: gate electrode

16: source electrode

17: body electrode

17A: first layer

17B: second layer

17C: third layer

18: drain electrode

20: trench

21: recess

117A: first Ni layer

117B: Mg layer

117C: second Ni layer

What is claimed is:

1. A semiconductor device comprising:
a semiconductor layer comprising a p-type Group III nitride semiconductor; and
an electrode located over the semiconductor layer, wherein
the electrode comprises a first layer located over and in contact with the semiconductor layer and a second layer located over and in contact with the first layer,
the first layer is made from a material containing Ni as a main component and containing 10% or less of Mg, and
the second layer comprises an alloy of Ni and Mg.

2. The semiconductor device according to claim 1, wherein the electrode further comprises a third layer located over and in contact with the second layer and containing Ni as a main component.

3. The semiconductor device according to claim 1, wherein a thickness of the first layer is 5 nm or more and 20 nm or less.

4. The semiconductor device according to claim 1, wherein a thickness of the second layer is 5 nm or more and 20 nm or less.

5. The semiconductor device according to claim 2, wherein a thickness of the third layer is 20 nm or more and 200 nm or less.

6. The semiconductor device according to claim 1, wherein a ratio of a thickness of the second layer to a total thickness of the electrode is 0.02 or more and 0.35 or less.

7. A method for producing a semiconductor device comprising:
forming, on a semiconductor layer containing a p-type Group III nitride semiconductor, an electrode in which a first Ni layer containing Ni, a Mg layer containing Mg, and a second Ni layer containing Ni are stacked in order from a side of the semiconductor layer at 100°C or lower, and then performing a heat treatment to the electrode.

8. A method for producing a semiconductor device comprising:
forming, on a semiconductor layer containing a p-type Group III nitride semiconductor, an electrode in which a first Ni layer containing Ni, a Mg layer containing Mg, and a second Ni layer containing Ni are stacked in order from a side of the semiconductor layer, and then performing a heat treatment to the electrode at a temperature of higher than 400°C and 600°C or lower.

9. A method for producing a semiconductor device comprising:
forming, on a semiconductor layer containing a p-type Group III nitride semiconductor, an electrode in which a first Ni layer containing Ni, a Mg layer containing Mg, and a second Ni layer containing Ni are stacked in order from a side of the semiconductor layer, and then performing a heat treatment to the electrode for a time of 2 minutes or longer and 10 minutes or shorter.

10. The method for producing a semiconductor device according to claim 7, wherein the heat treatment is performed at a temperature of higher than 400°C and 600°C or lower.

11. The method for producing a semiconductor device according to claim 7, wherein the heat treatment is performed for a time of 2 minutes or longer and 10 minutes or shorter.

12. The method for producing a semiconductor device according to claim 8, wherein the heat treatment is performed for a time of 2 minutes or longer and 10 minutes or shorter.

13. The method for producing a semiconductor device according to claim 7, wherein a thickness of the first Ni layer is 5 nm or more and 20 nm or less.

14. The method for producing a semiconductor device according to claim 8, wherein a thickness of the first Ni layer is 5 nm or more and 20 nm or less.

15. The method for producing a semiconductor device according to claim 9, wherein a thickness of the first Ni layer is 5 nm or more and 20 nm or less.

16. The method for producing a semiconductor device according to claim 7, wherein a thickness of the Mg layer is 5 nm or more and 20 nm or less.

17. The method for producing a semiconductor device according to claim 8, wherein a thickness of the Mg layer is 5 nm or more and 20 nm or less.

18. The method for producing a semiconductor device according to claim 7, wherein a thickness of the second Ni layer is 20 nm or more and 200 nm or less.

19. The method for producing a semiconductor device according to claim 7, wherein a ratio of a thickness of the Mg layer to a total thickness of the electrode is 0.02 or more and 0.35 or less.

20. The method for producing a semiconductor device according to claim 7, wherein the first Ni layer and the second Ni layer are formed by electron beam deposition, and the Mg layer is formed by resistance heating deposition.
